(19) United States
(12) Patent Application Publication
(10) Pub. No.: US 2019/0139844 A1
(43) Pub. Date: May 9, 2019

(54) METHOD FOR PROCESSING AN ELECTRICALLY INSULATING MATERIAL PROVIDING SAME WITH SELF-ADJUSTING ELECTRICAL FIELD GRADING PROPERTIES FOR ELECTRICAL COMPONENTS

(71) Applicants: UNIVERSITE TOULOUSE III - PAUL SABATIER, Toulouse (FR); CENTRE NATIONAL DE LA RECHERCHE SCIENTIFIQUE, Paris 16 (FR); INSTITUT NATIONAL UNIVERSITAIRE JEAN-FRANCOIS CHAMPOLLION, Albi Cedex 09 (FR)

(72) Inventors: Guillaume Belijar, Toulouse (FR); Sombel Diaham, Villeneuve Les Bouloc (FR); Thierry Lebey, Toulouse (FR); Louis Leveque, Plougastel-Daoulas (FR); Zarel Valdez Nava, Fourquevaux (FR); Lionel Laudebat, Castelmaurou (FR)

(21) Appl. No.: 16/307,340

(22) PCT Filed: Jun. 6, 2017
(86) PCT No.: PCT/EP2017/063740

§ 371 Date: Dec. 5, 2018

(30) Foreign Application Priority Data
Jun. 6, 2016 (FR) 1655173

(51) Int. Cl. H01L 23/29; H01L 21/56; H01L 21/67; C09D 163/00; C09D 7/61

(52) U.S. Cl. CPC H01L 23/29; H01L 21/56; C09D 7/61; C09D 163/00; H01L 21/67126

(57) ABSTRACT

A method for processing an electrically insulating protective material intended for covering at least one surface of an electrical component to be insulated, which includes first and second electrical contacts. The method includes: mixing an electrically insulating host matrix with a particulate filler having dielectric permittivity higher than that of the host matrix, so as to obtain a homogeneous composite mixture; depositing the solidifiable homogeneous composite mixture on the at least one surface of the electrical component to be insulated; applying an electrical field to the homogeneous composite mixture by using the first and second electrical contacts.

### 1. FIELD OF THE INVENTION

The invention is part of the field of electrically insulating material for electrical components. More specifically, the invention relates to a technique for processing an electrically insulating protective material designed to cover an electrical component to be insulated.

The invention can be applied especially but not exclusively to electronic systems, electronic power systems and electro-technical systems intended for the conversion and transportation of high-voltage electrical energy or to embedded electrical components (such as power converters, high-voltage transformers, gas-insulated switches, high-voltage connectors, elements for high-voltage transmission, high-voltage cables whether DC (Direct Current) or AC (Alternating Current), and bus-bars for example).

The term “electrical component” in this document must be interpreted in the broad sense and can correspond equally well to an electrical or electronic module, an electrical or electronic circuit, a PCB type printed circuit board, an electrical or electronic card or board, an electronic component, an electrical connector, an electrical cable, etc. More generally, the invention can be applied to any element with electrical or electronic functions, provided with electrical contacts that are to be covered with an electrical insulator.

### 2. TECHNOLOGICAL BACKGROUND

We shall strive more particularly here below in the invention to describe the problems and issues existing in the field of power electronics that the inventors have faced. The invention of course is not limited to this particular field of application but is of interest for all electrical protection techniques (encapsulation, passivation, tropicalization, enameling, impregnation, molding etc.) that have to cope with proximate or similar problems and issues.

Electrical insulation is a critical element in devices working under high voltage. Since the service life of an electrical component is often related to the service life of its insulation, research has been conducted in recent years to understand the causes of deterioration and ageing of materials used as solid electrical insulators, and especially in electronic power modules. These modules working under high voltage are subjected indeed to high electrical stresses, which may lead to the appearance of electrical field reinforcements in the insulating material (i.e. singular areas in proximity to conductive elements around which the electrical field is more intense). These field reinforcements (if certain voltage levels are reached) are sources of partial discharges, damaging the component as and when it is used, and even leading to electrical breakdown.

This is all the more noteworthy as the insulating materials used in current power components endure strains and stresses for which they do not necessarily have the right size. Indeed, the increase in operating voltages used combined with the great increase in the integration of electronics into embedded systems especially, is leading to an increase in the power density. The level of electrical stresses to be endured for insulating materials has therefore greatly increased.

One solution to ensuring improved voltage performance would be to oversize the constituent elements of the electrical components, but this approach is obviously not compatible with a search for optimizing integration.

One component frequently used in energy conversion systems for railway transport, for example, is the chip-based power module known as the IGBT (Insulated Gate Bipolar Transistor), as illustrated in FIG. 1. Its structure is constituted by a stack of different elements. One or more IGBT chips 1 are brazed to an insulating substrate 2 comprising an electrically insulating layer 21 (based on a ceramic material) that is covered on its lower and upper faces with a metallic electrical contact 22 and 23 (a metallization). The substrate 2 is a metalized ceramic substrate called a DBC (Direct Bonding Copper) or AMB (Active Metal Brazing) substrate because of the method by which it is obtained. In the most common case, this substrate is disposed on a support 5 made of copper or AlSiC. The different elements of the modules are assembled and covered with a layer of electrically insulating (encapsulating) material, then enclosed in a plastic package 6. The module is then fixed to a cooling system on the lower face of the module (not shown) in order to dissipate the heat produced in operation and then connected by conductors to the rest of the electrical circuit (actuators, sources etc.).

One of the main causes of failure in this component, from an electrical point of view, lies in the breaking of the electrical insulation at the triple ceramic/metal/insulator point, as illustrated in FIG. 2 (triple point referenced A) corresponding to the interface of three media with different permittivity values, and at the electrical contact point 22 (referenced B) at the metal/insulator interface (in this case the term used is “point effect”). These sensitive points are chiefly related to the geometry of the contacts that are obtained after etching and give rise to non-uniformity of the electrical field in the encapsulating material. An electrical field reinforcement localized in that insulator in the vicinity of these sensitive points can lead to the formation of partial electrical discharges that sometimes take the form of electrical treeing, the repetition of which causes deterioration in the encapsulating material 3 leading to premature ageing of the module, as well as problems of reliability, or limiting of voltage-withstand capacity.

With a view to achieving higher voltages and/or integrating power electronics while meeting the constraints related to high voltages, a known solution described in the patent document WO 2015/074431, and illustrated in FIG. 3 consists in depositing a thin layer or film of semi-resistive varnish 4 based on hydrogenated amorphous silicon on the ceramic layer 21 at the interface with the encapsulation material 3 from the upper electrical contact 22 up to the lower electrical contact 23. This layer of semi-resistive varnish 4 reduces the risk of partial discharges situated around the electrical contacts. However, such a solution requires the use of a plasma-deposition apparatus that is costly and difficult to achieve on an industrial scale. In addition, the masking of certain sensitive elements within the structure is relatively complicated given the variation of the structural elements that can compose it.

Another known solution described in a scientific publication by N. Hayakawa, et Al., 2012, entitled “Fabrication Technique of Permittivity Graded Materials (FGM) for Disk-Type Solid Insulator, Proceedings of the CEIDP”, relies on the making of a potential grading (or electrical field grading) material as an electrically insulating, encapsulating material for electronic components. The potential grading is done by a material with a permittivity gradient. This material is a composite based on a polymer matrix filled with particles of different sizes. Before being hardened, this composite material is subjected to a centrifugal force so as to cause the particles to move in the polymer matrix to obtain a certain profile of permittivity as a function of the spatial distribution of the particles.

However, the solution has a certain number of drawbacks. Because of the nature of the technique used to move the particles in the polymer matrix (centrifugation), it is possible to have only a unilateral movement of the particles in the matrix (in the sense opposite to the center of rotation of the material), and this is not optimal. This technique is restrictive because it enables the processing of only one localized area of the material (and not necessarily the totality of the areas that must be treated (the absence of partial discharges in the material is therefore not guaranteed)). This technique furthermore implies that the material should have a simple geometrical shape (cylindrical or circular). This solution moreover requires a re-machining of the encapsulating material subsequently to the steps of centrifugation and hardening. This is a painstaking and costly task to implement. Finally, it does seem to be compatible with the manufacture of bulky electrical components, such as power modules, transformers or high-voltage circuit breakers for example.

It therefore seems to be necessary to propose an innovative solution for electrical insulation that efficiently reduces the phenomenon of partial discharges in an electrical component and/or obtains higher operating voltages, and is simple and costs little to implement.

### 3. SUMMARY OF THE INVENTION

In one particular embodiment of the invention, a method is proposed for processing an electrically insulating protective material intended for covering at least one surface of an electrical component to be insulated comprising at least one electrical contact, the method comprising the following steps:
mixing an electrically insulating host matrix with a particulate filler having dielectric permittivity higher than that of the host matrix, so as to obtain a homogeneous composite mixture;
covering said at least one surface of the electrical component to be insulated with the homogeneous composite mixture ;
applying an electrical field to the homogeneous composite mixture by means of said at least one electrical contact so as to obtain a heterogeneous mixture.

The general principle of the invention therefore consists of the use of an electrical field during the preparation of the protective material based on an electrically insulating host matrix charged with particles having higher dielectric permittivity, to give it self-adaptive electrical field degrading properties. Indeed, the inventors have discovered that the application of an electrical field to such a homogeneous composite mixture prompts the movement of the particles in the host matrix in such a way that they get naturally concentrated in the zones to be processed (i.e. in the zones where the undesirable electrical field reinforcements can appear when the component is under voltage). This induces an increase in the dielectric permittivity and/or the electrical conductivity in a way that is targeted and automatically adapted to the defects of the electrical component. Thus, unlike in the prior art (where only a unilateral movement of the particles in the matrix is possible), the method of the invention offers a simple and efficient solution based on a self-adjustment of the profile of dielectric permittivity and/or electrical conductivity of the protective material when it is being prepared as a function of critical points truly present in the material. The heterogeneous composite material obtained therefore has a profile of dielectric permittivity and/or electrical conductivity that reduces the electrical field reinforcements which are sources of partial discharges of the electrical component during operation. The processing method according to the invention therefore ensures better voltage-withstand capacity in the electrical component and therefore increased service life.

According to one particular embodiment, the method furthermore comprises a step for hardening the composite mixture subsequently to the step for applying an electrical field.

This hardening step makes it possible to fix the spatial distribution of the particles obtained in the host matrix after electrical processing. Following this step, an electrically insulating and electrical field grading protective material is obtained.

According to one variant of an implementation, the method comprises a step for hardening the composite mixture that is implemented during the step for applying an electrical field.

This step for hardening makes it possible to fix the spatial distribution of the particles obtained in the host matrix during electrical processing. At the end of the step, an electrically insulating and electrical field grading protective material is obtained. This particular implementation is advantageous in terms of time because it makes it possible to carry out dual and parallel processing of the composite mixture.

In one particular implementation, the electrical field applied is a DC electrical field.

This particular implementation efficiently modulates the profile of concentration of the particles in the host matrix. It can be implemented for example to obtain a gradient of concentration of particles from the interface between the electrical contact and the protective material.

According to one particular characteristic, the electrical component comprises a first electrical contact of high potential and a second electrical contact of low potential, the electrical field being applied by means of a pre-determined potential difference (positive polarity or negative polarity) between said first and second contacts.

This makes it possible to favor a concentration of particles on either one of the electrical contacts should a DC electrical field be applied. For example, a concentration of particles at the interface with a high-voltage electrical supply contact could be favored since the risk of electrical field reinforcement around this contact will probably be greater.

In one variant of implementation, the electrical field applied is an AC electrical field.

This variant of implementation makes it possible to efficiently modulate the profile of concentration of the particles in the host matrix and is especially well suited to the electrical component having a configuration with symmetrical reinforcement. The electrical field can be applied by means of a square-shaped, triangular, sinusoidal or analog AC electrical signal.

According to a first particular implementation, the electrical field is applied with a frequency strictly above 10 Hz.

The inventors have discovered surprisingly that, by applying a “high frequency” electrical field (i.e. an electrical field with a frequency above 10 Hz), it is possible to form a relaxation layer for the electrical field extending between the first and second contacts in the form of particle chains (the particle chains having relative dielectrical permittivity higher than that of the rest of the heterogeneous composite mixture).

According to a second particular implementation, the electrical field is applied with a frequency lower than or equal to 10 Hz.

The inventors have also discovered, surprisingly, that by applying a “low frequency” electrical field (i.e. a field with a frequency lower than or equal to 10 Hz), first and second relaxation layers of the electrical field are obtained, disposed symmetrically on the first and second electrical contacts, respectively. The term “symmetrical” refers to the fact that two relaxation layers have similar shapes and thicknesses, through a symmetrical distribution of the particles in the protective material.

In this second implementation, the electrical field is applied by means of a first AC electrical signal of pre-determined shape that is superimposed on a second DC electrical signal.

The presence of a DC electrical signal superimposed on an AC electrical signal makes it possible to form, asymmetrically, first and second relaxation layers of the electrical field on the first and second electrical contacts respectively. The term “asymmetrical” refers to the fact that one of the relaxation layers created has a thickness greater than the other one. The AC electrical signal can have a square, sinusoidal, triangular or analog shape.

According to one particular characteristic, the electrical field is applied with an amplitude of less than 2 kV/mm. The electrical field applied ranges more particularly from 50 to 1000 V, and even more particularly from 100 to 500 V.

According to one particular characteristic, the host matrix has relative dielectric permittivity of 1 to 20 and the particulate filler has a dielectric permittivity higher than 2. The relative dielectric permittivity of the host matrix and of the particulate filler is chosen especially so that the relative dielectric permittivity of the electrical field relaxation layer of the heterogeneous composite mixture obtained is from 10 to 50 and more particularly is in the range of 25.

It must be noted that the relative dielectrical permittivity of the host matrix has been measured experimentally in the solid state with a frequency of 1 MHz and at a temperature of 25° C., and that the relative dielectric permittivity of the particulate filler has been measured experimentally in the solid state with a frequency of 50 Hz and at a temperature of 25° C.

The host matrix is obtained from a hardenable liquid polymer material and the particulate filler is obtained from a material belonging to the group comprising: SrTiO₃, BaTiO₃, Ba₁₋ₓSrₓTiO₃, SiC, Al₂O₃, AlN, BN, Si₃N₄, SiO₂, ZnO, MgO, CaCu₃Ti₄O₁₂, TiO₂, MoS₂, Ca₂Nb₃O₁₀, Si_{w}AlₓO_{y}N_{z}, polyvinylidene fluoride (PVDF) or polyamide (PA), etc.

This list of materials is not exhaustive. It must be noted that the host matrix can be obtained from materials that are thermally polymerizable (i.e. having characteristics of solidification under the effect of thermal processing) or photo-hardening (i.e. having characteristics of solidification under the effect of electromagnetic radiation). It must also be noted that the particulate filler can be obtained from one of the materials listed here above or a combination of these materials.

According to one particular characteristic, the ratio by volume of the particulate filler relative to the total volume of the homogeneous composite mixture ranges from 0.01% to 60% and more particularly from 10% to 60%. In certain particular cases, it is possible to envisage a ratio by volume of 60% to 70%.

This range of ratios by volume has shown good results in providing the protective material with the desired characteristics.

According one particular characteristic, the particulate filler is a filler based on micrometer-sized and/or nanometer-sized particles.

According to one particular characteristic, the particulate filler is a filler based on spherical and/or cylindrical and/or tubular and/or plane-shaped particles.

The size and the shape of the particles can have an impact on the electrical permittivity and/or the conductivity of the final encapsulation material, on its dielectric rigidity, on the partial discharge appearance threshold and endurance towards partial discharges.

According to one particular characteristic, the particulate filler is a filler based on particles having a composite structure of the core-shell type.

Thus, the particulate filler can comprise either particles that are homogeneous in their chemical composition or composite particles with a structure of the core-shell type or else a combination of the two.

According to one particular characteristic, said step of application of an electrical field is performed by means of an external connection part of the electrical component cooperating with said at least one electrical contact.

This characteristic is particularly advantageous since the presence of the external connection part enables the performance of the electrical processing of the encapsulation material with the structural elements of the electrical component itself. In certain cases, this averts the need to resort to an additional electrode system that comes into contact with said at least one electrical contact and which, furthermore, would necessitate modifying the structural architecture for certain electrical components with complex internal structures, to be able to carry out the step. In other cases, the addition of a temporary and detachable counter-electrode dedicated solely to the application of the electrical field during the method can be envisaged. The method mentioned is therefore simple and low cost in its implementation as compared with the methods of the prior art.

According to one alternative embodiment, said step for applying an electrical field is carried out by means of at least one temporary and detachable counter-electrode intended for electrical connection to said at least one electrical contact.

This variant can be used for example when the electrical component does not possess any external connection part cooperating with said at least one electrical contact where said external connection part is not easily accessible.

Another embodiment of the invention proposes a method for manufacturing an electrical component, comprising a step for making an electrical component to be insulated and a step for processing an electrically insulating protective material as described here above, in any one of its embodiments.

Another embodiment of the invention proposes an electrical component obtained by the method of manufacture as described here above.

Another embodiment of the invention proposes an electrically insulating protective material processed by the method described here above, in any one of its embodiments.

In another embodiment of the invention, there is proposed an electrically insulating protective material covering at least one surface of an electrical component be insulated, comprising at least one electrical contact, said at least one electrical contact forming an interface with said material which comprises a heterogeneous composite mixture composed of an electrically insulating host matrix and a particulate filler of relative dielectric permittivity higher that of the host matrix. In this particular embodiment, said material takes the form of a layer at least partially disposed on the surface of one electrical contact of said at least one electrical contact. In other words, said material has a concentration in particulate filler in the host matrix that is higher at the level of said interface.

Thus, the profile of concentration of the particles obtained enables concentration of the particles locally at the interface between said at least one electrical contact and the protective material. This spatial distribution of the particles enables the formation of a layer of increased dielectric permittivity at the interface between the protective material and the electrical contact (i.e. at the protective material/electrical contact interface).

In another embodiment of the invention, there is proposed an electrically insulating protective material covering at least one surface of an electrical component to be insulated comprising first and second electrical contacts, each of the first and second electrical contacts forming an interface with said material that comprises a heterogeneous composite material formed by an electrically insulating host matrix and a particulate filler with relative dielectric permittivity higher than that of the host matrix. In this particular embodiment, the particulate filler included in said material takes the form of chains of concentrated particles extending between the first and second contacts.

Thus, the profile of concentration of the particles obtained makes it possible to form a layer of increased dielectric permittivity anisotropically between the electrical contacts of the component.

Another embodiment of the invention proposes an electrically insulating protective material covering at least one surface of an electrical component to be insulated comprising first and second electrical contacts, said material comprising a heterogeneous composite mixture composed of an electrically insulating host matrix and a particulate filler having relative dielectric permittivity higher than that of the host matrix. In this particular embodiment, the particulate filler takes the form of first and second layers at least partially disposed on the surface of the first and second electrical contacts respectively.

Another embodiment of the invention proposes a device for processing an electrically insulating protective material intended to cover at least one surface of an electrical component to be insulated comprising at least one electrical contact, the device comprising:
means configured to mix an electrically insulating host matrix with a particulate filler with dielectric permittivity higher than that of the host matrix, so as to obtain a homogeneous composite mixture;
means configured to cover on said at least one surface of the electrical component to be insulated with the homogeneous composite mixture;
means configured to apply an electrical field to the homogeneous composite mixture by means of said at least one electrical contact.

### 4. LIST OF FIGURES

Other features and advantages of the invention shall appear from the following description, given by way of an indicative and non-exhaustive example, and from the appended drawings of which:

FIG. 1, already described with reference to the prior art, presents an example of an electrical power module known in the prior art;

FIG. 2, already described with reference to the prior art, presents a partial view in section of the electrical module illustrated in FIG. 1;

FIG. 3, already described with reference to the prior art, presents a known technique for reducing the formation of partial discharges in a power module as presented with reference to FIGS. 1 and 2;

FIG. 4 presents a flow chart of a particular embodiment of the method that is the object of the present invention;

FIG. 5 is a simplified block diagram representing the different steps of the method according to a first embodiment;

FIGS. 6A and 6B are partial views in section of a DBC type structure obtained under an optical microscope after processing of the protective material in accordance with the first embodiment;

FIG. 7 is a simplified block diagram representing the different steps of the method according to a second embodiment;

FIG. 8 is a partial view in section of a DBC type structure obtained under an optical microscope after processing of the protective material in accordance with the second embodiment;

FIGS. 9 and 10 are simplified block diagrams representing the steps of the method according to first and second variants of the second embodiment respectively;

FIGS. 11 and 12 represent examples of timing diagrams of the AC electrical field applied in the context of the first and second alternative embodiments illustrated respectively with reference to FIGS. 9 and 10.

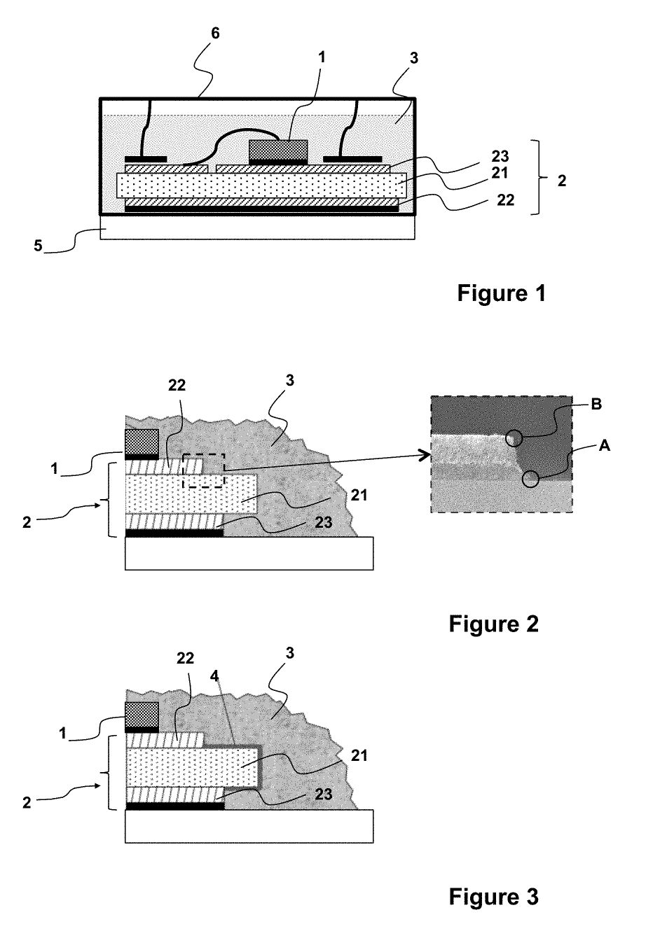

### 5. DETAILED DESCRIPTION

In all the figures of the present document, the identical elements and steps are designated by a same numerical reference.

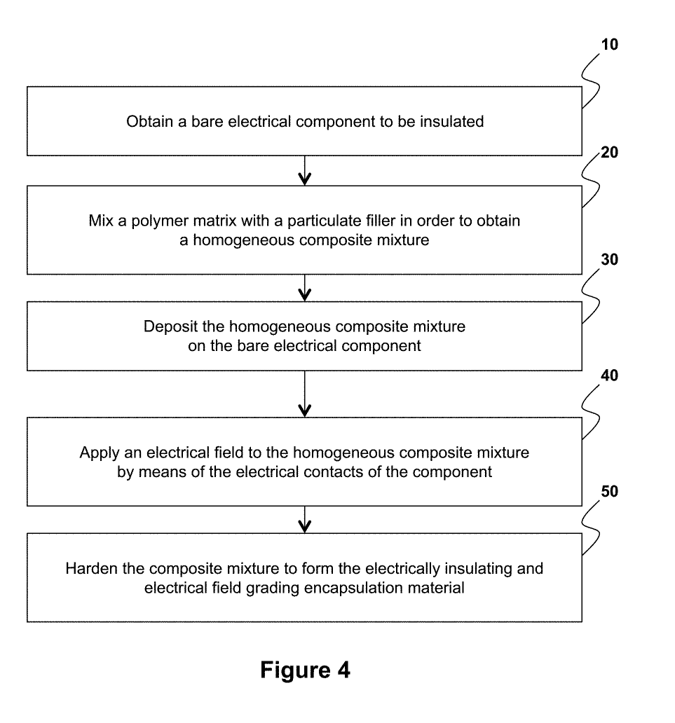

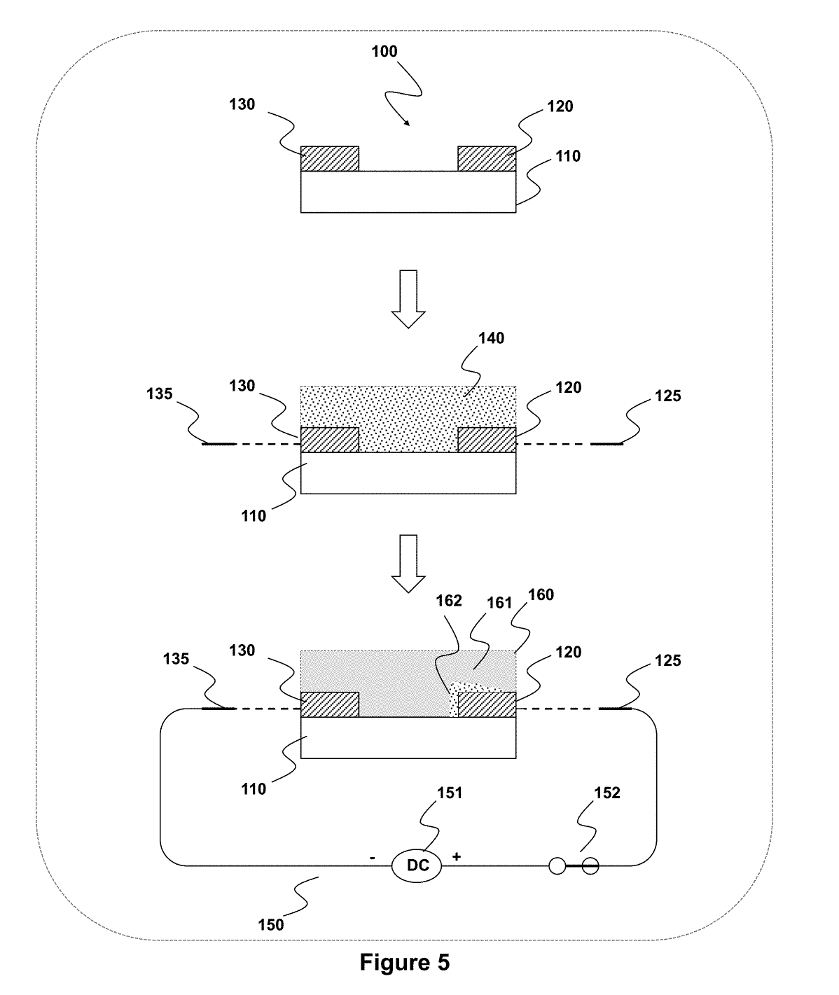

Here below, with reference to FIGS. 4 and 5, we describe the main steps of the method for manufacturing an electrical component according to one particular embodiment of the invention.

Step 10 for Making an Electrical Component to be Insulated

First of all, a bare electrical component is made. For example, this step 10, in the case of an IGBT or JFET (Junction Field Effect Transistor) based power module that has not yet been electrically insulated, the device is made by means of a technique of lithography or other well known techniques derived from microelectronics.

To simplify the figures and the associated description, the focus here is placed on one part only of the power module, namely the metalized ceramic substrate or DBC (Direct Bonding Copper) substrate of said module. The terms “component” and “module” will be used here below without distinction to designate the same structural element.

As illustrated in FIG. 5, the component 100 to be insulated comprises a layer of ceramic material 110 (for example a layer of aluminum oxide with the chemical formula Al₂O₃) on which there is laid out a first electrical contact 120, of high potential, connected to a high-voltage supply, and a second electrical contact 130, of low potential, connected to ground. The component to be insulated 100 also comprises another electrical contact (not illustrated in the figure) laid out on the lower face of the layer of ceramic material 110 and connected to ground. These elements form the metalized ceramic substrate. The component 100 to be insulated furthermore comprises a support made of copper (Cu) or aluminum-silicon carbide (AlSiC), commonly called a sole (not illustrated in the figure) on which the metalized ceramic substrate is disposed. The layer of ceramic material 110 has a relative dielectric permittivity of about 9.

The object of the following steps is to make an electrically insulating protective material (or encapsulating material) that is intended to cover the component 100 to be insulated, this material being prepared so as to reduce the formation of partial discharges when the component is under voltage and/or to make it possible to increase the operating voltage.

Step 20 for Making Hardenable Homogeneous Composite Mixture

First of all, a mixture is made out of an electrically insulating host matrix homogeneously charged with guest particles, also called particulate fillers. In the example described here, the host matrix is an epoxide-based liquid polymer matrix, commonly called an “epoxy resin” mixed with a hardener with a polymer/hardener ratio by weight of 10:1. The host matrix therefore constitutes a hardening liquid polymer medium. The particulate filler comprises inorganic particles coming from a strontium titanate powder (SrTiO₃) for example. The particles have a micrometric size typically ranging from 100 nm to 100 micrometers. Particles of nanometer size smaller than 100 nanometers can also be used alone or in combination with particles of micrometer size, without departing from the framework of the present invention. The strontium titanate particles have been chosen for their relative dielectric permittivity (or high dielectric constant) (typically ranging from 100 to 400 in the ground mass state) relative to that of the epoxide polymer matrix (typically ranging from 3 to 6).

A given quantity of micrometric particles of strontium titanate is introduced into the epoxide polymer matrix (comprising the hardener) and mixed by means of a planetary mixer. The ratio by volume of the particulate filler relative to the total volume of the composite is about 10%.

At the end of the step 20, we obtain a composite homogeneous mixture with an epoxide polymer matrix charged with strontium titanate particles, and called epoxide/SrTiO₃.

This is a purely illustratory example and other materials fulfilling the same function could be envisaged without departing from the framework of the invention. In general, to ultimately give the protective material its electrical field grading behavior, it is preferred to use the following for the performance of this step:

an organic polymer matrix having a relative dielectric permittivity lower than or equal to 20 (measured at 1 MHz and at 25° C. in the solid state), such as for example a thermo-hardening resin (polyester or epoxide, polyimide, polyesterimide etc.) thermoplastic resin (polyethylene, polyurethane, etc.) or again an elastomer resin (silicone gel or gum), and

a particulate filler having relative dielectric permittivity strictly higher than 2 (measured at 50 Hz and at 25° C. in the solid state), such as for example particulate fillers based on SrTiO₃, BaTiO₃, Ba₁₋ₓSrₓTiO₃, SiC, Al₂O₃, AlN, BN, Si₃N₄, SiO₂, ZnO, MgO, CaCu₃Ti₄O₁₂, TiO₂, MoS₂, Ca₂Nb₃O₁₀, Si_{w}AlₓO_{y}N_{z}, polyvinylidene fluoride (PVDF) or polyamide (PA) or a combination of these materials, the condition being that the relative dielectrical permittivity of the particulate filler should be strictly higher than that of the host matrix.

The particulate filler can include particles that have different sizes (micrometric and/or nanometric sizes) and are spherical and/or cylindrical and/or tubular and/or plane-shaped.

It is also possible to envisage, by way of an alternative in combination with the embodiment described here, the use of particles with a composite core-shell structure. These particles are constituted by a core formed by a first material and a shell formed by a second material.

It is also possible, by way of an alternative or in combination with the embodiment described here, to use electricity-conducting particles that can be likened to a particle having extremely high relative dielectric permittivity (generally, metals are characterized by their properties of electrical conduction rather than their dielectrical properties).

Similarly, the ratio by volume of the particulate filler initially introduced into the matrix relative to the total volume of the composite can be from 0.01% to 60%. As for the viscosity of the epoxide polymer resin, it is chosen in this example in the range of 10 to 10,000 mPa.s at ambient temperature (appreciably equal to 20° C.). But more generally, it can be chosen from a range of 10 to 100,000 mPa.s as a function of the physical-chemical characteristics of the materials chosen to form the composite material, as well as other parameters of the method that those skilled in art will be capable of grasping by means of routine trials within their scope (for example the viscosity of the resin, the amplitude and the shape of the electrical field applied, the temperature used in the method, etc. have an impact on the speed of growth of the layer of particles in the protective material).

Covering Step 30

This step consists in covering the component 100 to be insulated on the totality of its surface with the homogeneous epoxide/SrTiO₃ composite material obtained at the end of the previous step, in order to encapsulate it. To this end, an epoxide/SrTiO₃ composite homogeneous mixture 140 is deposited on the surface of the component, typically by means of a technique for depositing polymer by liquid means. This technique has several advantages: it is simple to implement, requires low cost in terms of equipment, enables the making of layers having large surface areas and variable micrometric or millimetric thicknesses. In addition, this technique can be easily transferred to industry.

Naturally, this composite material 140 can be formed by other deposition techniques, especially but not exclusively by chemical means (CSD or chemical solution deposition), dip coating, spin coating, doctor blade coating, meniscus coating, spray coating, ink-jet coating, screen-printing, extrusion, injection molding, molding, encapsulation, casting, impregnation etc.

At the end of this step, the component 100 to be insulated is covered with a composite epoxide/SrTiO₃ 140 mixture.

This step makes it possible to cover not only the electrical contacts 120 and 130 as illustrated in FIG. 5 but also the other elements of the electrical component not visible in the figure. Indeed, in this step, the different structural elements constituting the IGBT-transistor-based power module must be coated with this layer, the goal being to encapsulate and electrically insulate all these elements.

Only one externally accessible part of the electrical contacts 120 and 130 (referenced 125 and 135 respectively in the figure) is not covered with the composite mixture 140 and is accessible from the exterior of the component to enable a subsequent electrical connection (step 40).

Step 40 of Electrical Processing

This step of the method according to the invention consists in applying an electrical field to the composite mixture 140 so as to prompt the shifting of the particles of strontium titanate in the polymer matrix in order to obtain a profile of dielectric permittivity as a function of the spatial distribution of the particles adapted to the field reinforcement zones that the protective material could show under electrical stresses. Two particular techniques are proposed to carry out this electrical treatment: an application of a DC electrical field (electrophoresis) and an application of an AC electrical field (dielectrophoresis). The second technique is described below.

(i) Application of DC Electrical Field (Electrophoresis)

In one particular implementation, a DC electrical field (or more generally a field comprising a DC component) is created between the electrical contacts 120 and 130 of the component using means for application of a DC electrical field 150. These means comprise for example a DC voltage source 151 configured to carry the electrical contacts 120 and 130 to different electrical potentials, and a switch 152 to apply or not apply the electrical field depending on its position (open or closed). Advantageously, the poles of the voltage source 151 are electrically connected to the externally accessible parts 125 and 135 of the electrical component.

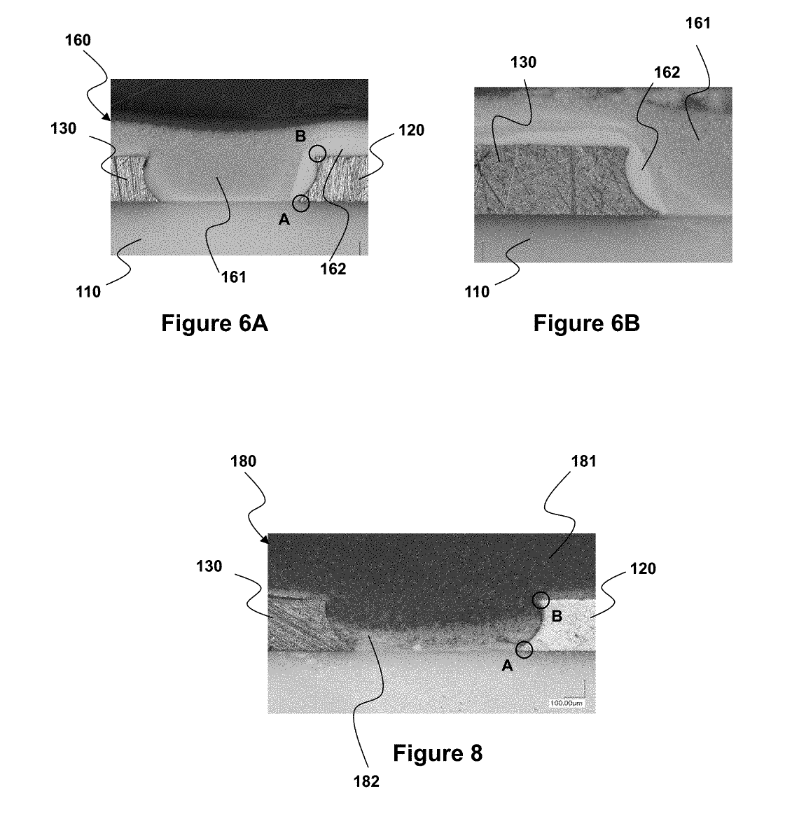

In practice, a DC voltage of amplitude 500 V is applied for example across the electrical contacts 120 and 130 which are at a distance 1 mm from each other (giving an electrical field of 500 V/mm), for about 15 minutes. This voltage is generated by applying a positive potential difference (for example +500 V) between the electrical contact 120 (connected to the high voltage) and the electrical contact 130 (connected to ground). This positive polarity configuration prompts the displacement of the strontium titanate particles towards the high-potential electrical contact 120 (i.e. towards the high-voltage power supply contact) and makes it possible to concentrate appreciably about this contact, as illustrated in FIG. 6A.

Naturally, it is possible, as an alternative, to envisage the application of a DC electrical field across the contacts 120 and 130 with a negative polarity configuration (i.e. by applying a negative voltage signal, for example −500 V, to the electrical contact 120), so as to prompt the shifting of the strontium titanate particles towards the low-potential electrical contact 130, as illustrated in FIG. 6B.

Thus, ingeniously, it is possible to accumulate the particles preferably either on the high-voltage metallization side or on the ground metallization side depending on the polarity of the electrical field applied.

At the end of this step of electrical processing, a composite mixture that is heterogeneous in terms of spatial distribution of the particles (and therefore in terms of dielectric permittivity of the material) is obtained.

The protective material 160 obtained by the method comprises a first composite part 161 with a concentration that is low in SrTiO₃ particles and a second composite part 162 that is more heavily charged in SrTiO₃, accumulated in the form of a layer called an electrical field relaxation layer. The thickness of the electrical field 162 relaxation layer is adjustable, for a given concentration of particles, depending especially on the level of the electrical field applied, the duration of application of this field, the viscosity of the initial host matrix, the shape and the nature of the guest particles.

Generally, a DC electrical field applied with an amplitude of 100 to 500 V/mm for a duration of 1 to 60 minutes has shown good results. Again more generally, it is possible to apply a DC voltage of an amplitude lower than 2,000V, and more particularly from 50 to 1,000V, without departing from the framework of the invention. The amplitude of the electrical field can be adapted especially according to the inter-electrode distance (the distance between the two electrical contact 120 and 130) to obtain the desired relaxation layer (in terms of thickness, concentration, etc.).

Trials within the scope of those skilled in the art make it possible to select the parameters and materials most appropriate depending on the spatial distribution of the particles desired and the electrical field grading properties ultimately desired for the protective material.

As illustrated in FIG. 6A, it can be seen that the use of a DC electrical field during the preparation of the protective material results especially in concentrating the strontium titanate particles locally about the “high voltage” electrical contact 120. This spatial distribution of the SrTiO₃ particles makes it possible to form a layer having increased dielectric permittivity at the interface between the protective material 160 and the electrical contact 120 (the insulator/metal interface). What is particularly worthwhile is that this layer (which has been created independently by electrophoretic process, covers, in a preferred way, the most brittle points known in the material such as the triple A ceramic/metal/insulator point and point B of the electrical contact. The experimental results and the simulations carried out by the inventors have shown that this spatial distribution of the SrTiO₃ particles has the effect of diminishing the gradient of dielectric permittivity at the metal/insulator interfaces and therefore reducing the formation of field reinforcements in the vicinity of the points A and B.

For example, the materials of the host matrix and of the particulate filler are chosen so that the first and second composite parts 161 and 162 of the protective material 160 have a relative dielectric permittivity in the vicinity of 12 and 25 respectively. More generally, the host matrix and the particulate filler are chosen so that: the host matrix has a relative dielectric permittivity ranging from 1 to 20 and the particulate load has a relative dielectric permittivity higher than 2 and preferably higher than 11, in such a way that the relative dielectric permittivity of the relaxation layer 162 obtained after processing is from 10 to 50.

The method of processing according to the invention therefore ensures the manufacture of an electrical component having better voltage-withstand capacity, fewer partial discharges and therefore an increased service life. Thus, inventors have used the DC electrical field applied to the composite mixture to enable the distribution, in a totally independent way, of the particles in the zones to be processed (zones having electrical field reinforcements). Indeed, owing to the electrical nature of the processing, the concentration profile of the particles in the composite material naturally follows the distribution and the reinforcements of the electrical field induced during the processing operation. The use of electrical processing is therefore particularly ingenious. A local increase in dielectric permittivity is induced naturally where necessary and in a self-structuring way as can be seen in FIGS. 6A and 6B. This self-structuring is particularly advantageous because it can make it possible to match other defects that it would be impossible to foresee during the manufacture of the electrical component, such as for example the presence of a singularity (or point effect) for example which might be situated beyond the usual sensitive zones.

(ii) Application of an AC Electrical Field (Dielectrophoresis)
a) Application of a “High Frequency” AC Electrical Field »

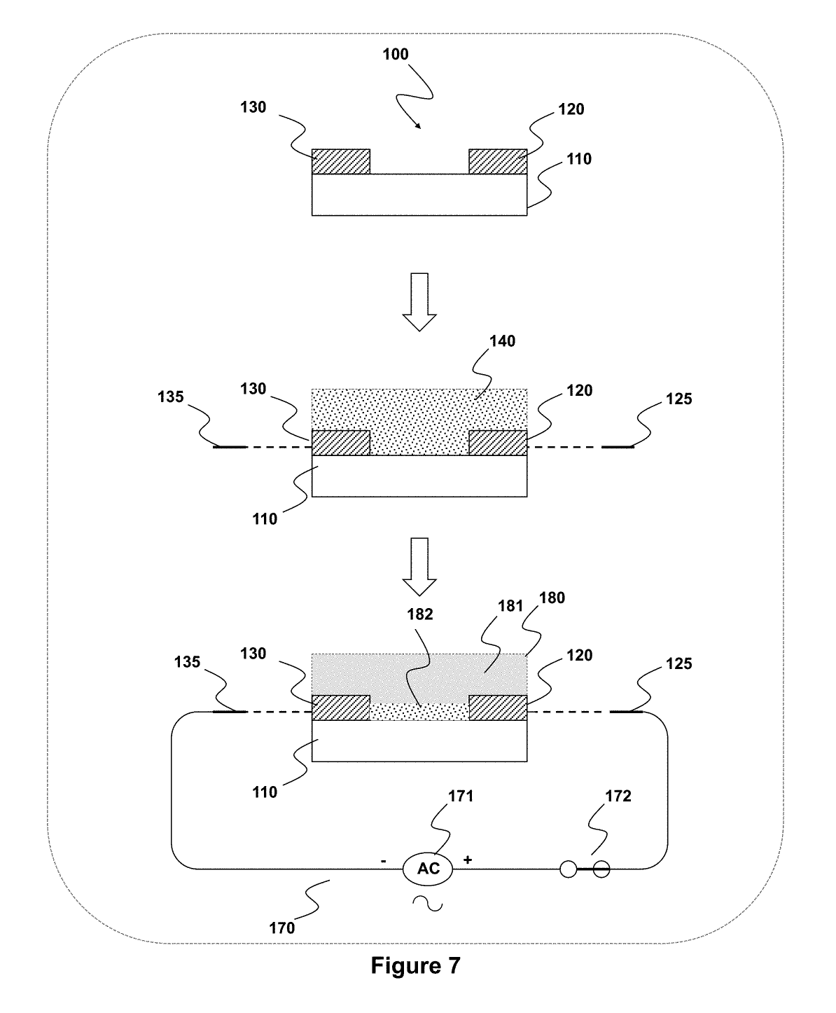

In this particular embodiment, the principle of which is illustrated in FIG. 7, an AC electrical field is created between the electrical contact 120 and 130 of the component using means for applying an AC electrical field 170. These means include for example an AC voltage source 171 configured to carry the electrical contacts 120 and 130 to different electrical potentials and at a given frequency, and a switch 172 used to apply or not apply the electrical field depending on its position (open or closed). Advantageously, the poles of the voltage source 171 are electrically connected to the externally accessible connection parts 125 and 135 of the component.

In the example illustrated here, a sinusoidal AC voltage with an amplitude 500V and frequency 1 kHz is applied across the electrical contacts 120 and 130 at a distance of 1 mm from each other, for a duration of about 15 minutes. Naturally, this is an illustratory and non-exhaustive example and other values of voltage, frequency and processing duration can be envisaged without departing from the framework of the invention. It is possible to envisage the application of a sinusoidal AC voltage with an amplitude below 2,000V, more particularly ranging from 50 to 1,000V and even more particularly from 100 to 500V. The electrical field will be adapted especially depending on the inter-electrode distance (the distance between the two electrical contacts 120 and 130).

However, it must be noted that to form a relaxation layer 182 in this specific form of particulate chains strictly extending between the electrical contacts 120 and 130, the AC electrical field must be applied with high frequency, i.e. a frequency strictly higher than 10 Hz. More particularly, the frequency can be from 11 to 100 kHz.

As in the case of the first embodiment, the thermal processing step 50 can also be done either subsequently to the step 40 or during the step 40 in its second embodiment.

The protective material with electrical insulation and dielectric permittivity gradient 180 comprises a composite part 181 with a low concentration in SrTiO₃ particles and a composite part 182 more highly charged in SrTiO₃ particles. The SrTiO₃ particles that accumulate take substantially the form of a layer 182, called a relaxation layer of the electrical field extending between the electrical contacts 120 and 130. The electrical and dielectrical properties of the relaxation layer of the electrical field 182 are adjustable for a given concentration of particles, depending especially on the level of the electrical field applied, its frequency, the duration of application of this field, the viscosity and permittivity of the initial host matrix, the size, the shape and the nature of the guest particles.

In general, an AC field applied with an efficacious value of 100 to 500 V/mm, a frequency of 11 Hz to 100 kHz for a duration of 1 to 60 minutes has shown efficient results. Even more generally, an AC field is effective when applied with an amplitude higher than or equal to 1 V/mm in a frequency range of 10 Hz to 10 MHz for a minimum duration of 1 second.

Trials within the scope of those skilled in the art make it possible to select the parameters and materials that are most appropriate depending on spatial distribution of the desired particles, the dielectric permittivity of the relaxation layer of the desired electrical field and the desired electrical field grading properties ultimately for the protective material.

As illustrated in FIG. 8, it can be seen that the application of a high frequency AC electrical field during the preparation of the protective material has the effect especially of forming chains of strontium titanate particles extending along the ceramic substrate 110 between the electrical contacts 120 and 130. Thus, in this particular embodiment, the concentration profile of the particles obtained is different since it enables the formation of a layer of dielectric permittivity that is anisotropically increased between the electrical contact 120 and 130 of the component. Such a profile efficiently increases the dielectric permittivity of the insulator, especially at the triple points of the electric contact.

Through the use of an AC electrical field, it is therefore possible to naturally induce an increase in the dielectric permittivity of the protective material in the areas to be treated, as can be seen in FIG. 8. This self-structuring is particularly advantageous because it makes it possible, inter alia, to counteract any defect that it would be impossible to predict during the manufacturing of the electrical component.
b) Application of a “Low Frequency” AC Electrical Field »

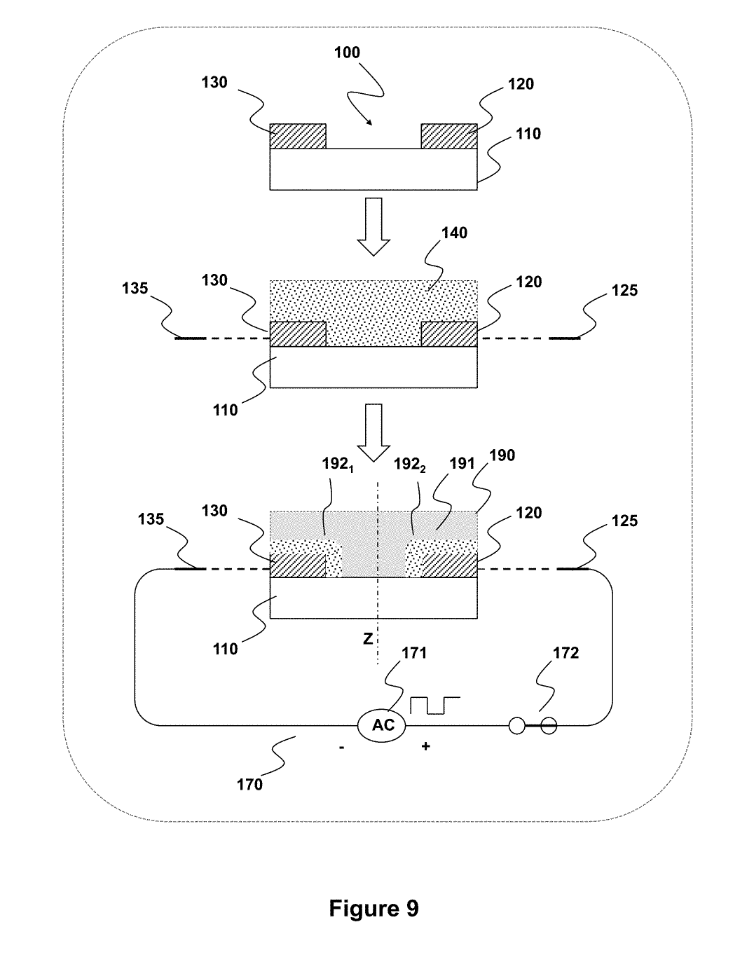

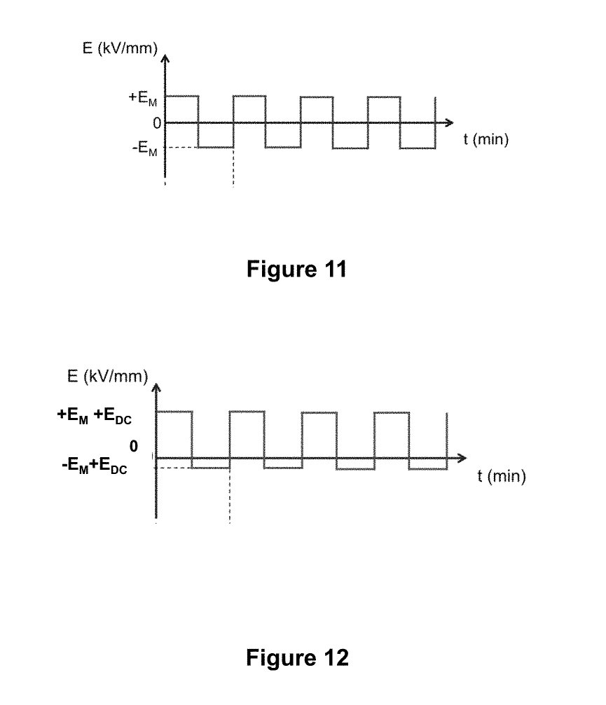

In this alternative implementation, the principle of which is illustrated in FIGS. 9 and 11, a low-frequency AC electrical field is applied across the two electrical contacts 120 and 130. Unlike the particular embodiment illustrated in FIG. 7, the AC electrical field is applied here with a frequency equal to or below 10 Hz.

The electrical processing is carried out here by applying a square-shaped periodic AC voltage across the electrical contacts 120 and 130, this voltage having an amplitude ranging from a maximum of +500 V to a minimum of −500V (giving 1 kV peak-to-peak), and a frequency of 10 mHz for a duration of about 15 minutes. The electrical contacts 120 and 130 are carried to the high potential and to ground respectively. The inter-electrode distance is still 1 mm. The resulting electrical field is illustrated in the timing diagram of FIG. 11: the peak-to-peak values plus +E_{M} and −E_{M} correspond to the maximum and minimum values of the electrical field applied to the composite mixture. It must be noted that the electrical field in this variant is symmetrical relative to the x axis which is equal to 0 kV/mm.

This electrical processing has the effect, by symmetrical displacement of the SrTiO₃ particles into the host matrix on each of the electrical contacts 120 and 130, of enabling the formation of two relaxation layers 192₁ and 192₂ of the electrical field with substantially identical thicknesses. The first relaxation layer 192₁ is formed here on the surface of the electrical contact 130 and first layer 1922 is formed on the surface of the electrical contact 120. The two relaxation layers 192₁ and 192₂ have a relative dielectric permittivity of over 10 and more particularly between 20 and 50. Thus, after electrical processing and thermal processing (the thermal processing can be done during or subsequently to the electrical processing step), the electrically insulating protective material 190 thus obtained comprises a composite part 191 with a low concentration of SrTiO₃ and two relaxation layers 192₁ and 192₂,highly charged in SrTiO₃ particles, extending on the surface of the electrical contacts 130 and 120 respectively.

The inventors have observed that, surprisingly, the application of a low-frequency electrical field across two electrical contacts during the preparation of the protective material prompts a symmetrical displacement of the particles of SrTiO3 in the host matrix towards each of the electrical contacts. After processing, the SrTiO₃ particles have a spatial distribution profile relative to the vertical axis Z of the component that is metrical.

Naturally, this is a non-exhaustive illustratory example. Other values of voltage, frequency and duration of processing can be envisaged without departing from the framework of the invention. Other forms of AC signals can also be envisaged, (such as a sinusoidal, triangular or analog signals for example).

In this alternative embodiment, it is possible to envisage the application of an AC field with a frequency lower than or equal to 10 Hz, more particularly lower than or equal to 1 Hz, more particularly lower than or equal to 0.100 Hz and even more particularly lower than or equal to 0.010 Hz, without departing from the framework of the invention.

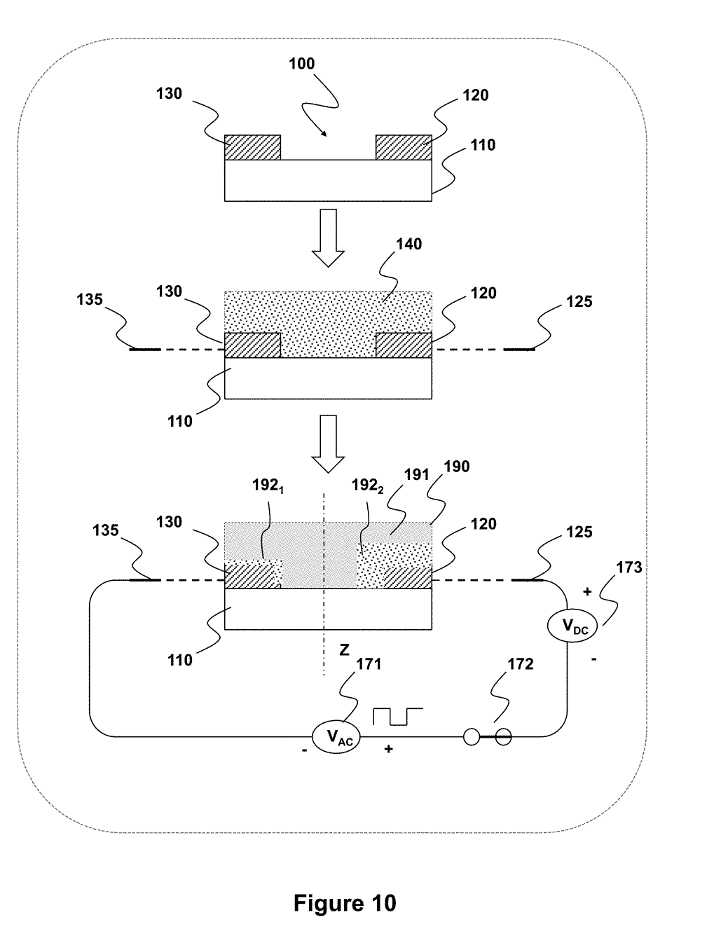

In a second particularly advantageous alternative embodiment, the principle of which is illustrated with reference to FIGS. 10 and 12, the AC electrical field is applied by means of a combination of two electrical signals: a first periodic AC electrical signal with a pre-determined shape (square, sinusoidal or analogue for example) and a second DC electrical signal called a “modulation” signal. This second electrical signal has the function of modulating the amplitude of the first electrical signal. Thus, unlike the first alternative embodiment of FIGS. 9 and 11, the electrical processing consists of the application of a periodic AC voltage but, in the presence of a supplementary DC voltage component (which can be positive or negative so as to modulate the maximum or minimum amplitude of the AC signal). This DC voltage component has the effect of making the timing diagram of the electrical field applied to the material asymmetrical relative to the X axis, as illustrated in FIG. 12.

Let us take the example of a periodic AC electrical signal of a square shape ((V_{AC}), with amplitudes maximum +500 V and minimum −500 V (giving 1 kV peak-to-peak), and frequency of 10 mHz, superimposed on a DC electrical signal (V_{DC}) with an amplitude of +400 V, the two electrical signals being applied for a duration of about 60 minutes. To this end, the application means 170 comprise an additional DC voltage source 173 series mounted with the AC voltage source 171.

The resulting electrical field in this alternative embodiment, is illustrated in the timing diagram of FIG. 12: the peak-to-peak values “+E_{M}+E_{DC}” and “−E_{M}+E_{DC}” correspond to the maximum and minimum values of the electrical field applied to the composite mixture. The electrical field thus created is offset positively relative to the X axis by an amplitude offset E_{DC}(+400 V/mm in this example) giving the asymmetrical profile of the relaxation layers as shown in FIG. 10.

As illustrated in FIG. 10, this particular electrical processing operation has the effect of shifting the SrTiO₃ particles in the host matrix towards the electrical contacts 120 and 130 but asymmetrically. In the particular instance illustrated herein (with a positive polarity configuration), the DC electrical signal “V_{DC}” is applied to the electrical contact 120, thus favoring a concentration of the SrTiO₃ particles on the surface of the electrical high potential contact 120 rather than towards the electrical low potential contact 110.

Hence, after electrical processing and thermal processing (this thermal processing can be done during or subsequently to the electrical processing step), the electrically insulating protective material 190 comprises a composite part 191 with a low concentration in SrTiO3 particles and having two relaxation layers 192₁ and 192₂, highly charged in SrTiO₃ particles but with unequal thicknesses. More specifically, the relaxation layer 192₂ (the contact layer 120) has a thickness greater than that of the relaxation layer 192₂,(contact 110 side).

The inventors have noticed that, surprisingly, the application of a low frequency and asymmetrical electrical field (asymmetrical from the viewpoint of the electrical potentials) across two electrical contacts prompts a shifting of the SrTiO₃ particles in the host matrix, preferably towards one of the electrical contacts. Thus, as illustrated in FIG. 10, the SrTiO₃ particles, after processing, take the form of a spatial distribution profile asymmetrical to the vertical axis Z of the component. The asymmetrical shape of the spatial distribution profile of the SrTiO₃ particles is therefore intimately related to the asymmetrical shape of the AC electrical signal applied to the material during its manufacture.

Thus, in modulating the AC electrical signal with an additional DC electrical signal, it is possible, in a targeted way, to collect the SrTiO₃ particles on one electrical contact rather than on the other. If no electrical modulation signal (“V_{DC}”) is generated, the thickness of two relaxation layers accumulated on the two electrical contacts is identical, and the symmetrical dielectric permittivity profile discussed further above with reference to FIGS. 9 and 11 is found again.

Naturally, this is a non-exhaustive illustratory example. As in the case of the first variant, other values of voltage, frequency and processing time can be envisaged without departing from the framework of the invention. Other shapes of AC signals can also be envisaged (such as a sinusoidal, triangular or analog signals for example).

Hardening Step 50

The method then carries out hardening of the heterogeneous composite material by means of a thermal treatment (also called a solidification annealing processing). To this end, the component is introduced into an oven, the temperature is then taken to 150° C. (with a gradient of 15° C./min) under air for a duration of 15 minutes. This step is used to enable the hardening of the liquid host matrix by reticulation of the polymer molecules and therefore to fix the spatial distribution of the particles thus obtained at the end of the step 40. Here, a house thermal processing operation is performed. It is quite possible, instead of a thermally polymerizable liquid polymer matrix, to use another type of liquid polymer matrix reacting to treatment by electromagnetic radiation (UV radiation or microwaves for example). Trials within the scope of those skilled in the art will make it possible to set the parameters (temperature level, duration, rising and descending gradient, electromagnetic radiation source etc.) for hardening suited to the chosen liquid polymer matrices.

At the end of this step, an electrically insulating and electrical field grading protective material (or encapsulation material) 160 or 180, as explained here above, is obtained.

According to one alternative implementation, it is possible to carry out the thermal processing step not subsequently to the step 40 as discussed here above but during the very step 40 itself, which is more optimal in terms of processing time (the thermal processing and the electrical processing being carried out in parallel).

The embodiments described here above propose the use of the externally accessible connection parts of the component to apply an electrical field across the electrical contacts to which they are connected. This enables the electrical processing to be performed in situ in the protective material with the structural elements of the electrical component itself. This approach is simple and costs little to implement. It also has the advantage of being adaptable to any type of electrical component, even with complex internal structures. However, it can be envisaged, as an alternative, that the application of the electrical field according to the invention will be carried out by means of a dedicated set of electrodes to be electrically connected to the electrical field application means (for example the addition of at least one temporary and detachable counter-electrode dedicated solely to the application of the electrical field during the method described here above).

The method described here above is intended for the manufacture of electrical power modules and components. It is clear however that it can easily be adapted to other applications without departing from the framework of the present invention such as for example for the manufacture of high-voltage electrical cables. In this case, the protective sheet of the cable corresponds to the electrically insulating protective material and the core of the cable corresponds to the single electrical contact of the component. The method of manufacture described here above can be applied, with the appropriate modifications, to the manufacture of such an electrical component. In particular, it is then possible to envisage the application of an electrical field according to the principle of the invention to give the electrical field grading properties on the protective material implemented by means of a difference in potential between the core of the cable and a distant counter-electrode. More generally, the invention can be applied to any electrical system having one or more electrical field reinforcements.

1. A method for processing an electrically insulating protective material intended for covering at least one surface of an electrical component to be insulated comprising first and second electrical contacts, the method comprising the following acts:
mixing an electrically insulating host matrix with a particulate filler having a dielectric permittivity higher than that of the host matrix, so as to obtain a homogeneous composite mixture;
covering said at least one surface of the electrical component to be insulated with the homogeneous composite mixture; and
subsequently to said covering, applying an electrical field, of frequency lower than or equal to 10 Hz, to the homogeneous composite mixture by means of the first and second electrical contacts, so as to obtain a heterogeneous mixture.

2. The method according to claim 1, further comprising hardening the composite mixture subsequently to applying the electrical field.

3. The method according to claim 1, further hardening the composite mixture during the act of applying an electrical field.

4. (canceled)

5. (canceled)

6. (canceled)

7. (canceled)

8. (canceled)

9. The method according to claim 1, wherein the electrical field is applied by means of a first AC electrical signal of pre-determined shape that is superimposed on a second DC electrical signal.

10. The method according to claim 1, wherein the electrical field is applied with an amplitude of less than 2 kV/mm

11. The method according to claim 1, wherein the host matrix has relative dielectric permittivity of 1 to 20 and the particulate filler has a dielectric permittivity higher than 2.

12. The method according to claim 1, wherein said act of applying an electrical field is performed by means of an external connection part of the electrical component cooperating with one of said first and second electrical contacts.

13. The method according to claim 1, wherein the act of applying an electrical field is carried out by means of at least one temporary and detachable counter-electrode intended for electrical connection to one of said first and second electrical contacts.

14. A method for manufacturing an electrical component, comprising making the electrical component to be insulated and, processing the electrically insulating protective material according to claim 1.

15. An electrical component comprising:
first and second electrical contacts;
at least one surface which is covered with an electrically insulating protective material, said material comprising a heterogeneous composite mixture composed of an electrically insulating host matrix and a particulate filler of relative dielectric permittivity higher that of the host matrix, said material comprising first and second relaxation layers disposed on a surface respectively of said first and second electrical contacts.

16. The electrical component according to claim 15, wherein said first and second relaxation layers have a substantially identical thickness.

17 The electrical component according to claim 15, wherein said first and second relaxation layers have different thicknesses.

18. (canceled)

19. A device for processing an electrically insulating protective material intended to cover at least one surface of an electrical component to be insulated comprising first and second electrical contacts, the device comprising:
means configured to mix an electrically insulating host matrix with a particulate filler of dielectric permittivity higher than that of the host matrix, so as to obtain a homogeneous composite mixture;
means configured to cover said at least one surface of the electrical component with the homogeneous composite mixture;
means configured to apply an AC electrical field, of a frequency lower than or equal to that of the homogeneous composite mixture by means of said first and second electrical contacts.
